(19) United States
(12) Patent Application Publication
(10) Pub. No.: US 2013/0207146 A1
(43) Pub. Date: Aug. 15, 2013

(54) LIGHT-EMITTING DEVICE

(71) Applicants: Kenichi Yoshimura, Osaka-shi (JP); Kohsei Takahashi, Osaka-shi (JP); Hiroshi Fukunaga, Osaka-shi (JP); Naoto Hirosaki, Tsukuba-shi (JP)

(72) Inventors: Kenichi Yoshimura, Osaka-shi (JP); Kohsei Takahashi, Osaka-shi (JP); Hiroshi Fukunaga, Osaka-shi (JP); Naoto Hirosaki, Tsukuba-shi (JP)

(73) Assignee: Sharp Kabushiki Kaisha, Osaka-shi, Osaka (JP)

(21) Appl. No.: 13/811,996

(22) PCT Filed: Jul. 15, 2011
(86) PCT No.: PCT/JP2011/066230

§ 371 Date: Feb. 28, 2013

(30) Foreign Application Priority Data
Jul. 26, 2010 (JP) 2010-167064

(51) Int. Cl. H01L 33/50

(52) U.S. Cl. CPC H01L 33/504
USPC 257/98

(57) ABSTRACT

There is realized a light-emitting device that emits, with high efficiency, white light with excellent color rendering index in a lamp color region. A light-emitting device (1) of the present invention is a light-emitting device (1) for emitting white light in a lamp color region, including at least a light-emitting element (2) for emitting blue light, an orange fluorescent material (13) which absorbs the blue light so as to emit orange light, and a red fluorescent material (14) which absorbs the blue light so as to emit red light, the orange fluorescent material (13) being a Ce-activated CaAlSiN₃ fluorescent material in a solid solution crystal form in which Ce and oxygen are dissolved in a crystal having a composition of cCaAlSiN₃.(1−c)LiSi₂N₃ where 0.2≦c≦0.8.

### TECHNICAL FIELD

The present invention relates to a light-emitting device including a fluorescent material.

### BACKGROUND ART

A semiconductor light-emitting element such as a light-emitting diode (LED) has advantageous features of (i) being small in size, (ii) consuming less electric power, and (iii) stably emitting light with high luminance. In recent years, there has been tendency to replace a lighting apparatus such as an incandescent lamp with a lighting apparatus including a light-emitting device made up of an LED that emits white light. Examples of the LED that emits white light encompass a light-emitting device in which a blue LED is combined with a Ce-activated YAG fluorescent material expressed by a compositional formula (Y,Gd)₃(Al,Ga)₅O₁₂: Ce.

In the light-emitting device thus configured, white light is obtained by mixing blue light emitted by the blue LED and yellow light emitted by the Ce-activated YAG fluorescent material. In this configuration, a red component is not sufficient due to emission properties of the Ce-activated YAG fluorescent material, and therefore the light-emitting device is not suitable for emitting light having a color similar to a lamp color, i.e., warm white light that a household lighting apparatus is expected to emit.

Under the circumstances, a light-emitting device has been disclosed in which a red fluorescent material, which is a nitride fluorescent material, is incorporated with a blue LED and a Ce-activated YAG fluorescent material so that the light-emitting device can emit warm white, i.e., red-tinged white (for example, see Patent Literature 1).

It is disclosed in Patent Literature 1 that the configuration can provide the light-emitting device that emits white light with a high color rendering index (Ra), in particular, with an excellent special color rendering index (R9) that indicates how red looks, at a color temperature of 3250 K or less in a lamp color region.

Further, in recent years, a fluorescent material has been proposed which is made up of, as host crystal, CaAlSiN₃ crystal containing at least Li, Ca, Si, Al, O, N, and Ce (for example, see Patent Literature 2). It is disclosed that the fluorescent material is suitably used to provide a white LED by being combined with a blue LED.

### CITATION LIST

### Patent Literatures

[Patent Literature 1]
Japanese Patent Application Publication Tokukai No. 2003-321675 A (Publication date: Nov. 14, 2003)
[Patent Literature 2]
WO 2010/110457 A1 (Publication date: Sep. 30, 2010)

### SUMMARY OF INVENTION

### Technical Problem

However, the configuration disclosed in Patent Literature 1 has a problem that emission efficiency of the light-emitting device is considerably low.

Specifically, in the configuration disclosed in Patent Literature 1, the red fluorescent material absorbs fluorescence emitted by the Ce-activated YAG fluorescent material, and mutual absorption between the fluorescent materials is influential. This considerably decreases the light emitting efficiency of the light-emitting device.

Patent Literature 2 does not disclose at all a technique to emit white light with excellent color rendering index in the lamp color region, by inhibiting the red fluorescent material from absorbing fluorescence emitted by an orange fluorescent material. Further, Patent Literature 2 does not disclose a configuration for inhibiting the red fluorescent material from absorbing fluorescence emitted by the orange fluorescent material, neither. Therefore, it is impossible to emit, with high efficiency, white light with excellent color rendering index in the lamp color region.

The present invention was made in view of the foregoing problems. An object of the present invention is to realize a light-emitting device that emits, with high efficiency, white light in a lamp color region with excellent color rendering index.

### Solution to Problem

In order to provide a light-emitting device that achieves high color rendering index with emitted light and that exhibits high luminous efficiency as described above, the inventors of the present invention have repeatedly manufactured by way of trial a fluorescent material and a light-emitting device including the fluorescent material and a semiconductor light-emitting element. As a result, the inventors of the present invention have found that a combination of members mentioned below could provide a light-emitting device that solves the foregoing problems, and completed the present invention. The following will describe the present invention in detail.

In order to solve the foregoing problems, a light-emitting device of the present invention is a light-emitting device for emitting white light in a lamp color region, including at least a light-emitting element for emitting blue light, an orange fluorescent material which absorbs the blue light so as to emit orange light, and a red fluorescent material which absorbs the blue light so as to emit red light, the orange fluorescent material being a Ce-activated CaAlSiN₃ fluorescent material in a solid solution crystal form in which Ce and oxygen are dissolved in a crystal having a composition of cCaAlSiN₃.(1−c)LiSi₂N₃ where 0.2≦c≦0.8.

With the arrangement, the light-emitting device of the present invention includes the red fluorescent material and the orange fluorescent material designed as above, so that it is possible to prevent the red fluorescent material from absorbing fluorescence emitted from the orange fluorescent material. Therefore, it is possible to provide a light-emitting device capable of emitting, with a high efficiency, white light in a lamp color region with excellent color rendering index.

### Advantageous Effects of Invention

As described above, the light-emitting device of the present invention is a light-emitting device for emitting white light in a lamp color region, including at least a light-emitting element for emitting blue light, an orange fluorescent material which absorbs the blue light so as to emit orange light, and a red fluorescent material which absorbs the blue light so as to emit red light, the orange fluorescent material being a Ce-activated CaAlSiN₃ fluorescent material in a solid solution crystal form in which Ce and oxygen are dissolved in a crystal having a composition of cCaAlSiN₃.(1−c)LiSi₂N₃ where 0.2≦c≦0.8.

Therefore, it is possible to provide a light-emitting device capable of emitting, with a high efficiency, white light in a lamp color region with excellent color rendering index.

### BRIEF DESCRIPTION OF DRAWINGS

FIG. 1 is a cross sectional view schematically showing a configuration of a light-emitting device in accordance with the present embodiment.

FIG. 2 is a graph showing a chromaticity point region of a lamp color defined by JIS Z9112.

FIG. 3 is a graph showing emission spectrum of a fluorescent material powder obtained in Production Example 1-1.

FIG. 4 is a graph showing excitation spectrum of a fluorescent material powder obtained in Production Example 1-1.

FIG. 5 is a graph showing emission spectrum of a fluorescent material powder obtained in Production Example 1-2.

FIG. 6 is a graph showing excitation spectrum of a fluorescent material powder obtained in Production Example 1-2.

FIG. 7 is a graph showing emission spectrum of a fluorescent material powder obtained in Production Example 1-3.

FIG. 8 is a graph showing excitation spectrum of the fluorescent material powder obtained in Production Example 1-3.

FIG. 9 is a graph showing Li-concentration-dependency of emission intensity of a solid solution crystal in which Ce and oxygen are dissolved.

FIG. 10 is a graph showing Li-concentration-dependency of full width at half maximum of emission spectrum of a solid solution crystal in which Ce and oxygen are dissolved, when excited by light having a wavelength of 450 nm.

FIG. 11 is a graph showing emission spectrum of a fluorescent material powder obtained in Production Example 2.

FIG. 12 is a graph showing emission spectrum of a fluorescent material powder obtained in Production Example 3.

FIG. 13 is a graph showing emission spectrum of a light-emitting device obtained in Example 1.

FIG. 14 is a graph showing emission spectrum of a light-emitting device obtained in Example 2.

FIG. 15 is a graph showing emission spectrum of a light-emitting device obtained in Example 3.

FIG. 16 is a graph showing emission spectrum of a light-emitting device obtained in Example 4.

FIG. 17 is a graph showing emission spectrum of a light-emitting device obtained in Example 5.

FIG. 18 is a graph showing emission spectrum of a light-emitting device obtained in Example 6.

FIG. 19 is a graph showing emission spectrum of a light-emitting device obtained in Comparative Example 1.

### DESCRIPTION OF EMBODIMENTS

The following describes an embodiment of the present invention. It should be noted that in the specification, the expression “A-B” used to indicate a range indicates being not less than A and not more than B. Physical properties mentioned in the specification were obtained by methods described in later-mentioned Examples, unless otherwise stated.

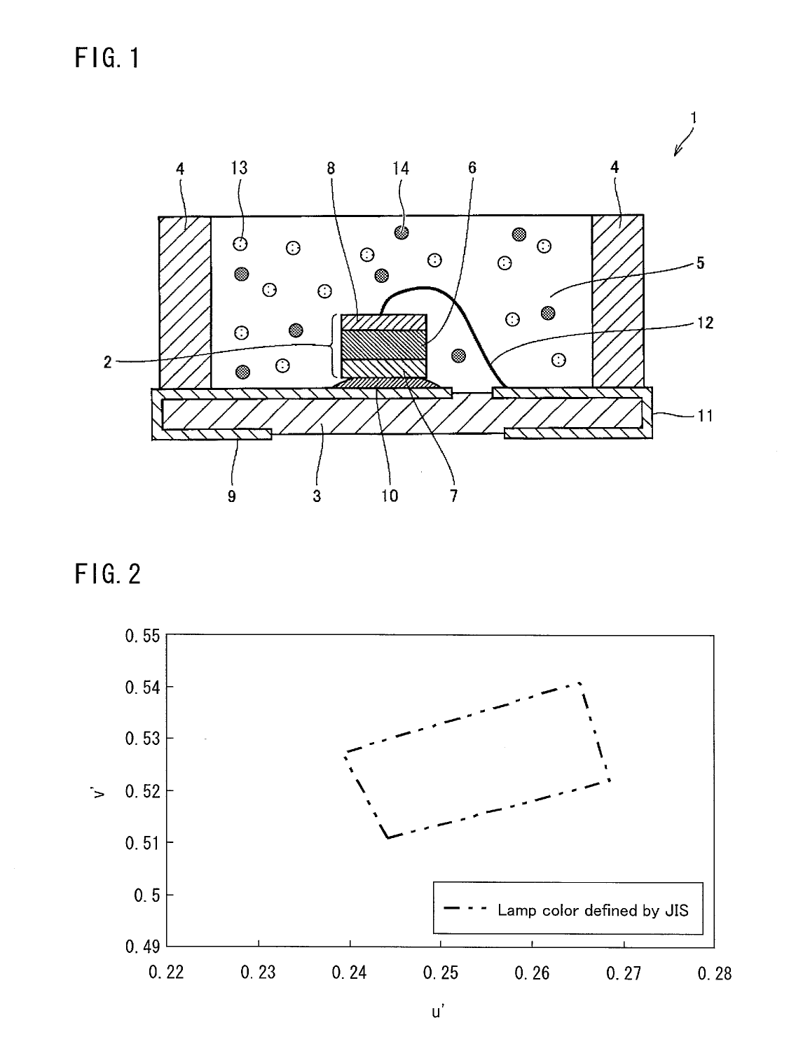

FIG. 1 is a cross sectional view schematically showing a configuration of a light-emitting device in accordance with the present embodiment.

A light-emitting device 1 in accordance with the present embodiment is a light-emitting device 1 for emitting white light in a lamp color region, including at least a semiconductor light-emitting element 2 for emitting blue light, an orange fluorescent material 13 which absorbs the blue light so as to emit orange light, and a red fluorescent material 14 which absorbs the blue light so as to emit red light.

In the specification, “blue light” indicates light whose peak of emission spectrum is 420-480 nm in wavelength. “Green light” indicates light whose peak of emission spectrum is 500-550 nm in wavelength. “Yellow light” indicates light whose peak of emission spectrum is 551-569 nm in wavelength. “Orange light” indicates light whose peak of emission spectrum is 570-630 nm in wavelength. “Red light” indicates light whose peak of emission spectrum is 631-680 nm in wavelength.

“Green fluorescent material” is a material that emits the green light. “Yellow fluorescent material” is a material that emits the yellow light. “Orange fluorescent material” is a material that emits the orange light. “Red fluorescent material” is a material that emits the red light.

“White light in a lamp color region” indicates that correlated color temperature (TCP) of emitted light is in a range of 2600K-3250K, and chromaticity point of the emitted light is in a range defined by JIS Z9112 shown in FIG. 2.

The light-emitting device 1 in accordance with the present embodiment is designed such that the semiconductor light-emitting element 2 is provided on a printed wiring substrate 3 serving as a substrate, and a resin frame 4 on the printed wiring substrate 3 is filled with a mold resin 5 made up of translucent resin in which the orange fluorescent material 13 and the red fluorescent material 14 are dispersed, so that the semiconductor light-emitting element 2 is sealed.

The semiconductor light-emitting element 2 includes (i) an InGaN layer 6 as an active layer and (ii) a p-side electrode 7 and an n-side electrode 8 with the InGaN layer 6 therebetween. The n-side electrode 8 is electrically connected via a conductive adhesive 10 with an n-electrode section 9 provided on the printed wiring substrate 3 from an upper surface thereof to a back surface thereof. The p-side electrode 7 is electrically connected via a metal wire 12 with a p-electrode section 11 which is provided, separately from the n-electrode section 9, on the printed wiring substrate 3 from an upper surface thereof to a back surface thereof.

It should be noted that the light-emitting device 1 in accordance with the present embodiment is not limited to the structure shown in FIG. 1 and may employ a structure of a conventional and publicly known light-emitting device in general.

### (I) Light-Emitting Element

In the present embodiment, the semiconductor light-emitting element 2 is used as a light-emitting element, and the semiconductor light-emitting element 2 is a light emitting diode (LED). However, the semiconductor light-emitting element 2 is not limited to a light emitting diode (LED), and may be conventional and publicly known elements that emit blue light, such as semiconductor laser and inorganic EL (electroluminescence) element. The LED may be a commercially available one manufactured by Cree, Inc. for example.

Emission peak wavelength of the semiconductor light-emitting element 2 is not particularly limited, but preferably 420-480 nm in consideration of luminous efficiency. The emission peak wavelength is more preferably in a range of 440-470 nm in consideration of increasing excitation efficiency of the fluorescent material and increasing Ra and R9. When the emission peak wavelength is not less than 455 nm and not more than 470 nm, the semiconductor light-emitting element 2 exhibits particularly high color rendering index.

### (II) Orange Fluorescent Material

The orange fluorescent material 13 is a Ce-activated CaAlSiN₃ fluorescent material in a solid solution crystal form in which Ce and oxygen are dissolved in a crystal having a composition of cCaAlSiN₃.(1−c)LiSi₂N₃ where 0.2≦c≦0.8. c in the formula is more preferably 0.3≦c≦0.7.

Among the Ce-activated CaAlSiN₃ fluorescent material, the orange fluorescent material made up of the above solid solution crystal has longer peak wavelength of emission spectrum and broader full width of half maximum of the emission spectrum than a Ce-activated YAG fluorescent material. Accordingly, in a case where the orange fluorescent material made up of the above solid solution crystal is combined with a red fluorescent material, mutual absorption by the red fluorescent material is subdued compared with, for example, a case where the Ce-activated YAG fluorescent material is combined with a red fluorescent material. This is because a color of light emitted from the orange fluorescent material made up of the above solid solution has a stronger red component than a color of light emitted from the Ce-activated YAG fluorescent material.

Therefore, when manufacturing a light-emitting device that emits white light in a lamp color region, use of the orange fluorescent material made of the above solid solution crystal is preferred to use of the Ce-activated YAG fluorescent material. It is more preferable that full width of half maximum of emission spectrum of the orange fluorescent material made up of the above solid solution crystal is not less than 130 nm. Although the upper limit of the full width of half maximum of emission spectrum of the orange fluorescent material is not particularly limited, the full width of half maximum is preferably not more than 150 nm.

In order to broaden full width at half maximum of emission spectrum, Li concentration of the orange fluorescent material is preferably not less than 1.4 weight %. In the light-emitting device in accordance with the present embodiment, as the full width at half maximum of emission spectrum of the orange fluorescent material 13 is broader, it is possible to realize a light-emitting device with higher color rendering index and higher luminous efficiency.

In consideration of luminous efficiency, Li concentration of the orange fluorescent material is preferably not more than 4 weight %.

In order that the Ce-activated fluorescent material is a solid solution crystal in which Ce and oxygen are dissolved in a crystal having the above composition, it is necessary to incorporate, for example, at least one kind of oxide of a constitutional metal element such as CeO₂ into a raw material powder.

When a semiconductor light-emitting element is used for a lighting apparatus etc., it is necessary to flow a large amount of a current compared with when the semiconductor light-emitting element is used for an indicator etc., and ambient temperature of the semiconductor light-emitting element reaches as high as 100-150° C. For example, as disclosed in Japanese Patent Application Publication No. 2008-127529, under a high temperature circumstance where ambient temperature is 150° C., a YAG: Ce fluorescent material described in Japanese Patent Application Publication No. 2003-321675 drops its luminous intensity down to 50% of luminous intensity at a room temperature. In contrast to such a conventional fluorescent material, an oxynitride fluorescent material described in the present specification has excellent emission properties under a high temperature circumstance in particular, and similarly with the fluorescent material described in Non-patent Literature (Science and Technology of Advanced Materials 8 (2007) 588-600), under a high temperature circumstance where ambient temperature is 100-150° C., the oxynitride fluorescent material can maintain luminous intensity of approximately 85-90% of luminous intensity at a room temperature.

It is preferable that a fluorescent material included in the light-emitting device in accordance with the present embodiment has emission properties under high temperature circumstance similar to those of the fluorescent material described in the above Non-patent Literature. In consideration of this, it is preferable that Ce concentration in the solid solution crystal in which Ce and oxygen are dissolved is more than 0 weight % and not more than 6 weight %.

Particle size of the orange fluorescent material 13 is preferably 1-50 μm, and more preferably 5-20 μm. The shape of a particle is preferably a single particle, not agglomerate. Specifically, specific surface area of the particle is preferably not more than 1 m²/g, and more preferably not more than 0.4 m²/g. For such particle size control and particle shape control, techniques such as mechanical pulverization, removal of grain boundary phase by acid treatment, and annealing treatment can be used appropriately.

### (III) Red Fluorescent Material

The light-emitting device 1 in accordance with the present embodiment includes a red fluorescent material 14 in addition to the light-emitting element 2 for emitting blue light and the orange fluorescent material 13. This allows realizing a light-emitting device that emits white light in a lamp color region.

Preferable examples of the red fluorescent material 14 include an Eu-activated nitride fluorescent material and oxynitride fluorescent material because of their high stability and excellent temperature characteristics.

Preferable examples of the Eu-activated nitride fluorescent material and oxynitride fluorescent material include Eu-activated MAlSiN₃ (M=Ca, Sr) fluorescent material described in Japanese Patent Application Publication No. 2006-8721 and Eu-activated M_{2-z}Si₅O_{z}N_{8-z} (M=Ba, Sr, Ca) (0<z<1) fluorescent material described in Japanese Patent Application Publication No. 2006-206729. Among them, the Eu-activated MAlSiN₃ (M=Ca, Sr) fluorescent material is particularly preferable because of its high luminous efficiency and excellent stability in temperature characteristics etc.

In the specification, “,” in the expression such as “M=Ca, Sr” indicates “and/or”. That is, “M=Ca, Sr” indicates “M is Ca and/or Sr”.

Full width at half maximum of emission spectrum of the red fluorescent material 14 is preferably not less than 70 nm in consideration of increasing Ra and R9 of the light-emitting device. Although the upper limit of the full width at half maximum of emission spectrum of the red fluorescent material 14 is not particularly limited, the upper limit is preferably not more than 120 nm.

### (IV) Green Fluorescent Material

The light-emitting device in accordance with the present embodiment may include a green fluorescent material in addition to the orange fluorescent material 13 and the red fluorescent material 14.

It is preferable that full width at half maximum of emission spectrum of the green fluorescent material is narrower than that of the orange fluorescent material 13. Specifically, full width at half maximum of emission spectrum of the green fluorescent material is preferably not more than 70 nm, and more preferably not more than 55 nm. Furthermore, although the lower limit of the full width at half maximum of emission spectrum of the green fluorescent material is not particularly limited, the lower limit is preferably not less than 15 nm and more preferably not less than 40 nm.

When the full width at half maximum of emission spectrum of the green fluorescent material is within the above range, absorption of green light by the orange fluorescent material 13 is subdued, so that a light-emitting device having further higher luminous efficiency can be realized.

The green fluorescent material is not particularly limited as long as it meets the above requirements. A preferable example of the green fluorescent material is an Eu-activated oxynitride fluorescent material because of its high stability and excellent temperature characteristics.

Furthermore, preferable examples of the Eu-activated oxynitride fluorescent material include an Eu-activated BSON fluorescent material described in Japanese Patent Application Publication No. 2008-138156 and an Eu-activated β sialon fluorescent material described in Japanese Patent Application Publication No. 2005-255895 that have excellent luminous efficiency.

Among them, the Eu-activated β sialon fluorescent material in particular has excellent stability and temperature characteristics, and has particularly narrow full width at half maximum of emission spectrum, exhibiting excellent luminous characteristics.

Specifically, the Eu-activated BSON fluorescent material is preferably a fluorescent material having a composition of Ba_{y′}, Eu_{x′}, Si_{u′}, O_{v′}, N_{w′} where 0≦y′≦3, 1.6≦y′+x′≦3, 5≦u′≦7, 9<v′<15, 0<w′≦4. More preferable ranges of y′, x′, u′, v′, and w′ are that 1.5≦y′≦3, 2≦y′+x′≦3, 5.5≦u′7, 10<v′<13, 1.5<w′≦4.

Specifically, the Eu-activated β sialon fluorescent material is preferably a fluorescent material having a composition of Si_{6-z′}, Al_{z′}, O_{z′}, N_{8-z′} where 0<z′<4.2 and activated with Eu. A more preferable range of z′ is 0<z′<0.5.

It is preferable to arrange the Eu-activated β sialon fluorescent material such that its oxygen concentration is 0.1-0.6 weight % and its Al concentration is 0.13-0.8 weight %. When oxygen concentration and Al concentration of the Eu-activated β sialon fluorescent material are within the above ranges, full width at half maximum of emission spectrum is likely to be narrower.

The Eu-activated β sialon fluorescent material disclosed in International Publication WO2008/062781 has removed a damage phase of the fluorescent material by an after-treatment such as an acid treatment after sintering, and accordingly has little unnecessary absorption and high luminous efficiency. Furthermore, the Eu-activated β sialon fluorescent material disclosed in Japanese Patent Application Publication No. 2008-303331 has oxygen concentration of 0.1-0.6 weight %, and accordingly has narrow full width at half maximum of emission spectrum, which is preferable.

To be more specific, a preferable example of the green fluorescent material is one in which an absorption ratio of light at 600 nm which is a wavelength region not contributing to light emission of a β sialon fluorescent material and is close to a peak wavelength of the orange fluorescent material is not more than 10%.

The particle size of the green fluorescent material is preferably 1-50 μm, and more preferably 5-20 μm. The shape of a particle is preferably a single particle, not agglomerate. Specifically, specific surface area of the particle is preferably not more than 1 m²/g, and more preferably not more than 0.4 m²/g. For such particle size control and particle shape control, techniques such as mechanical pulverization, removal of grain boundary phase by acid treatment, and annealing treatment can be used appropriately.

In a case where the green fluorescent material used in the present embodiment is an Eu-activated oxynitride fluorescent material and the orange fluorescent material 13 is a Ce-activated nitride fluorescent material or Ce-activated oxynitride fluorescent material, both of the orange fluorescent material 13 and the green fluorescent material are nitrides and accordingly have similar temperature-dependency, specific gravity, particle size etc.

Therefore, the light-emitting device with the above configuration can be manufactured with good yield, and the light-emitting device has high reliability hardly influenced by ambient environment. In addition, since the nitride fluorescent material has strong covalent bonding of host crystals, the nitride fluorescent material has little temperature-dependency in particular and is highly resistant to chemical and physical damages.

### (V) Mold Resin

In the light-emitting device 1, the mold resin 5 used for sealing the semiconductor light-emitting element 2 is obtained by dispersing the orange fluorescent material 13 in, for example, translucent resin such as silicone resin and epoxy resin. A method of dispersion is not particularly limited and may be a conventional and publicly known one.

A ratio of mixing the orange fluorescent material 13, the red fluorescent material 14, and the green fluorescent material to be dispersed is not particularly limited and may be determined appropriately so that white light in a lamp color region is emitted. For example, a weight ratio of the translucent resin to the orange fluorescent material 13, the red fluorescent material 14, and the green fluorescent material (weight of translucent resin/weights of orange fluorescent material 13, red fluorescent material 14, and green fluorescent material) may be in a range of 2-20.

Furthermore, in consideration of increasing luminous efficiency of the light-emitting device, a weight ratio of (red fluorescent material 14)/(fluorescent material other than red fluorescent material 14) is preferably low. This is due to mutual absorption of the red fluorescent material absorbing fluorescence from other fluorescent material. Specifically, in a case of the weight ratio of (red fluorescent material 14)/(fluorescent material other than red fluorescent material 14)<0.2, the mutual absorption is sufficiently subdued and a light-emitting device with high luminous efficiency can be realized. Furthermore, the lower limit of the weight ratio of (red fluorescent material 14)/(fluorescent material other than red fluorescent material 14) is not less than 0.001.

Furthermore, a weight ratio of the green fluorescent material to the orange fluorescent material 13 (weight ratio of green fluorescent material/orange fluorescent material 13) may be in a range of 0.05-1.

### (VI) Others

In the light-emitting device 1 in accordance with the present embodiment, members other than the light-emitting element 2, the orange fluorescent material 13, the red fluorescent material 14, the green fluorescent material, and the mold resin 5, i.e. members such as the printed wiring substrate 3, the adhesive 10, and the metal wire 12 may be configured in the same manner as in the conventional art (e.g. Japanese Patent Application Publication No. 2003-321675, Japanese Patent Application Publication No. 2006-8721 etc.), and may be produced in the same manner as in the conventional art.

The present invention described as above can be reworded as follows.

(1) A semiconductor light-emitting device for emitting white light in a lamp color region, including at least a semiconductor light-emitting element for emitting blue light, an orange fluorescent material which absorbs the blue light so as to emit orange light, and a red light which absorbs the blue light so as to emit red light, the orange fluorescent material being a Ce-activated CaAlSiN₃ fluorescent material in a solid solution crystal form in which Ce and oxygen are dissolved in a crystal having a composition of cCaAlSiN₃.(1−c)LiSi₂N₃ where 0.2≦c≦0.8.

(2) The semiconductor light-emitting device as set forth in (1), wherein a weight ratio of the red fluorescent material to a fluorescent material other than the red fluorescent material is less than 0.2.

(3) The semiconductor light-emitting device as set forth in (1), wherein full width at half maximum of emission spectrum of the orange fluorescent material is not less than 140 nm.

(4) The semiconductor light-emitting device as set forth in (1), wherein the red fluorescent material is an Eu-activated nitride fluorescent material or an oxynitride fluorescent material.

(5) The semiconductor light-emitting device as set forth in (1), wherein full width at half maximum of emission spectrum of the red fluorescent material is not less than 70 nm.

(6) The semiconductor light-emitting device as set forth in (1), wherein the red fluorescent material is an Eu-activated MAlSiN₃ fluorescent material (M=Ca, Sr).

(7) The semiconductor light-emitting device as set forth in (1), further including a green fluorescent material in addition to the red fluorescent material and the orange fluorescent material.

(8) The semiconductor light-emitting device as set forth in (7), wherein full width at half maximum of emission spectrum of the green fluorescent material is not more than 55 nm.

(9) The semiconductor light-emitting device as set forth in (7), wherein the green fluorescent material is an Eu-activated β sialon fluorescent material.

(10) The semiconductor light-emitting device as set forth in (7), wherein oxygen concentration of the Eu-activated β sialon ranges from 0.1 weight % to 0.6 weight %.

(11) The semiconductor light-emitting device as set forth in (7), wherein an absorption ratio of light of the Eu-activated β sialon fluorescent material at 600 nm is not more than 10%.

The present invention encompasses aspects as follows.

In order to solve the foregoing problems, the light-emitting device of the present invention is a light-emitting device for emitting white light in a lamp color region, including at least a light-emitting element for emitting blue light, an orange fluorescent material which absorbs the blue light so as to emit orange light, and a red fluorescent material which absorbs the blue light so as to emit red light, the orange fluorescent material being a Ce-activated CaAlSiN₃ fluorescent material in a solid solution crystal form in which Ce and oxygen are dissolved in a crystal having a composition of cCaAlSiN₃.(1−c)LiSi₂N₃ where 0.2≦c≦0.8.

With the arrangement, the light-emitting device of the present invention includes the red fluorescent material and the orange fluorescent material designed as above, so that it is possible to prevent the red fluorescent material from absorbing fluorescence emitted from the orange fluorescent material without greatly dropping color rendering index. Therefore, it is possible to provide a light-emitting device capable of emitting, with a high efficiency, white light in a lamp color region with excellent color rendering index.

It is preferable to arrange the light-emitting device of the present invention such that a weight ratio of the red fluorescent material to a fluorescent material other than the red fluorescent material is less than 0.2.

With the arrangement, it is possible to prevent the red fluorescent material from absorbing fluorescence emitted from other fluorescent material, so that it is possible to provide a light-emitting device with a higher luminous efficiency.

It is preferable to arrange the light-emitting device of the present invention such that full width at half maximum of emission spectrum of the orange fluorescent material is not less than 130 nm.

With the arrangement, it is possible to prevent the red fluorescent material from absorbing fluorescence emitted from other fluorescent material, so that it is possible to provide a light-emitting device with a higher luminous efficiency.

It is preferable to arrange the light-emitting device of the present invention such that the orange fluorescent material contains Li in a range of not less than 1.4 weight % and not more than 4 weight %.

With the arrangement, as described in later-mentioned Examples, it is possible to increase full width at half maximum of emission spectrum, so that it is possible to maintain high emission intensity. Therefore, it is possible to provide a light-emitting device with high color rendering index and high luminous efficiency.

It is preferable to arrange the light-emitting device of the present invention such that the red fluorescent material is an Eu-activated nitride fluorescent material or an oxynitride fluorescent material.

With the arrangement, it is possible to provide a light-emitting device with high stability in temperature characteristics etc.

It is preferable to arrange the light-emitting device of the present invention such that full width at half maximum of emission spectrum of the red fluorescent material is not less than 70 nm.

With the arrangement, it is possible to provide a light-emitting device that exhibits higher Ra and R9.

It is preferable to arrange the light-emitting device of the present invention such that the red fluorescent material is an Eu-activated MAlSiN₃ fluorescent material (M=Ca, Sr).

With the arrangement, it is possible to provide a light-emitting device with higher stability and higher luminous efficiency.

It is preferable to arrange the light-emitting device of the present invention so as to further include a green fluorescent material in addition to the red fluorescent material and the orange fluorescent material.

With the arrangement, it is possible to provide a light-emitting device with higher luminous efficiency and higher Ra and R9.

It is preferable to arrange the light-emitting device of the present invention such that full width at half maximum of emission spectrum of the green fluorescent material is not more than 55 nm.

With the arrangement, higher values of Ra and R9 are obtained, and absorption of green light by the other fluorescent material is prevented sufficiently, so that it is possible to provide a light-emitting device with higher luminous efficiency.

It is preferable to arrange the light-emitting device of the present invention such that the green fluorescent material is an Eu-activated β sialon fluorescent material.

The Eu-activated β sialon fluorescent material is efficiently excited by blue light, and as a result of excitation by blue light, the Eu-activated β sialon fluorescent material emits light that meets the requirements of the present invention.

It is preferable to arrange the light-emitting device of the present invention such that an absorption ratio of light of the Eu-activated β sialon fluorescent material at 600 nm is not more than 10%.

With the arrangement, unnecessary absorption of orange light by the green fluorescent material is prevented, so that it is possible to provide a light-emitting device with higher luminous efficiency.

The present invention is not limited to the description of the embodiments above, but may be altered by a skilled person within the scope of the claims. An embodiment based on a proper combination of technical means disclosed in different embodiments within the scope of the claims is encompassed in the technical scope of the present invention.

### EXAMPLES

The following description will discuss the present invention in more detail with reference to Examples and Comparative Examples although the present invention is not limited to such examples.

[Excitation Spectrum and Emission Spectrum]

The excitation spectrum and emission spectrum were measured with the use of F-4500 (product name, manufactured by Hitachi, Ltd.). The excitation spectrum was measured by scanning the intensity of light emission at its emission peak. The emission spectrum was measured by exciting light which has a wavelength of 450 nm.

[Absorption Spectrum]

The absorption spectrum of a fluorescent material powder was measured with the use of a measurement system in which a spectrometer (product name: MCPD-7000, manufactured by Otsuka Electronics Co. Ltd.) and an integrating sphere were used in combination.

[Li Concentration and Ce Concentration in Fluorescent Material Powder]

The Li concentration and Ce concentration in the fluorescent material powder were measured with the use of ICP (product name: IRIS Advantage, manufactured by Nippon Jarrell-Ash Co. Ltd.).

[Powder X-Ray Diffraction]

Powder X-ray diffraction (XRD) was carried out with the use of a Kα line of Cu.

### Production of Fluorescent Material

### Production Example 1-1

### Production 1 of Orange Fluorescent Material

With a crystal of the 0.6CaAlSiN₃.0.4LiSi₂N₃ composition as a host crystal, chemical synthesis was carried out in order to obtain a fluorescent material in which the host crystal is activated with Ce.

Specifically, in order to obtain a compound represented by a theoretical composition formula Ce_{0.0017}Li_{0.0664}Ca_{0.0996}Al_{0.0996}Si_{0.2324}O_{0.0025}N_{0.4979}, raw powders of Si₃N₄, AlN, Li₃N, Ca₃N₂, and CeO₂ were weighed with the compositional ratios of 51.9 wt %, 19.5 wt %, 3.7 wt %, 23.5 wt %, 1.4 wt %, respectively, in such a manner that the entire weight was set to 2.0 g, (ii) the raw materials thus weighed were mixed together for 10 minutes with the use of an agate pestle and a mortar, and then (iii) the mixture thus obtained was dropped in free fall into a pot made of boron nitride until the pot was filled with the mixture by 38% (of the volume filling ratio). Note that all the steps involved in the weighing and mixing of the powders were carried out in a glove box capable of maintaining therein a nitrogen atmosphere in which the moisture content and the oxygen content are each 1 ppm or less.

Subsequently, in order for the mixture to be calcined, a boron-nitride pot containing the mixture was placed in an electric furnace with a graphite resistance heating system. The operation of calcination was carried out as follows: (i) inside of the electric furnace was vacuumized with the use of a diffusion pump, (ii) a temperature of the inside of the electric furnace was raised from a room temperature to 800° C. at speed of 1200° C. per hour, (iii) nitrogen with 99.999 volume % purity was introduced into the inside of the electric furnace so as to set the atmospheric pressure to 0.92 MPa, (iv) the temperature of the inside of the electric furnace was raised to 1800° C. at speed of 600° C. per hour, and then (v) the temperature of the inside of the electric furnace was maintained at 1800° C. for 2 hours.

Following the calcination, excess Li₃N was removed from the calcined substance by water-rinsing. Then, the calcined substance thus processed was roughly crushed and then crushed by hands with the use of an aluminum mortar, so that a fluorescent material powder was obtained.

Note that the fluorescent material powder contained an oxide material as a raw powder, and was therefore a solid solution crystal in which Ce and oxygen were dissolved.

Table 2 shows the Ce concentration and the Li concentration of the fluorescent material powder which were obtained with the use of the ICP and compositions of individual fluorescent materials which were obtained from the Li concentration. Note that the Li concentration, which was lower than 2.20 wt % in the theoretical composition, is considered to be the result of Li evaporation during the calcination and of the water-rinsing after the calcination.

As a result of examining the fluorescent material powder with the use of powder X-ray diffraction (XRD), it was confirmed that the fluorescent material powder possesses a crystalline structure in which a CaAlSiN₃ phase is a main phase. Additionally, as a result of radiating the fluorescent material powder with light having a wavelength of 365 nm, it was confirmed that the fluorescent material powder emits orange light in such a condition.

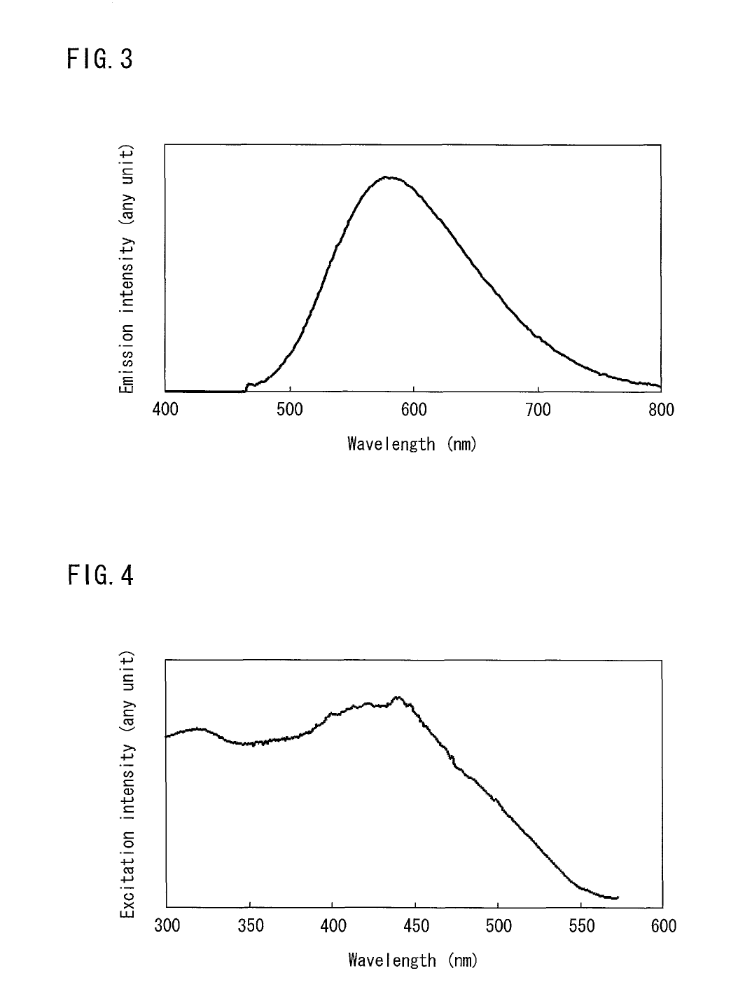

FIG. 3 is a graph showing the emission spectrum of the fluorescent material powder. The longitudinal and lateral axes of FIG. 3 represent emission intensity (any given unit) and wavelength (nm), respectively. Table 3 shows (i) chromaticity coordinates of, a peak wavelength of, and full width at half maximum of the emission spectrum shown in FIG. 3.

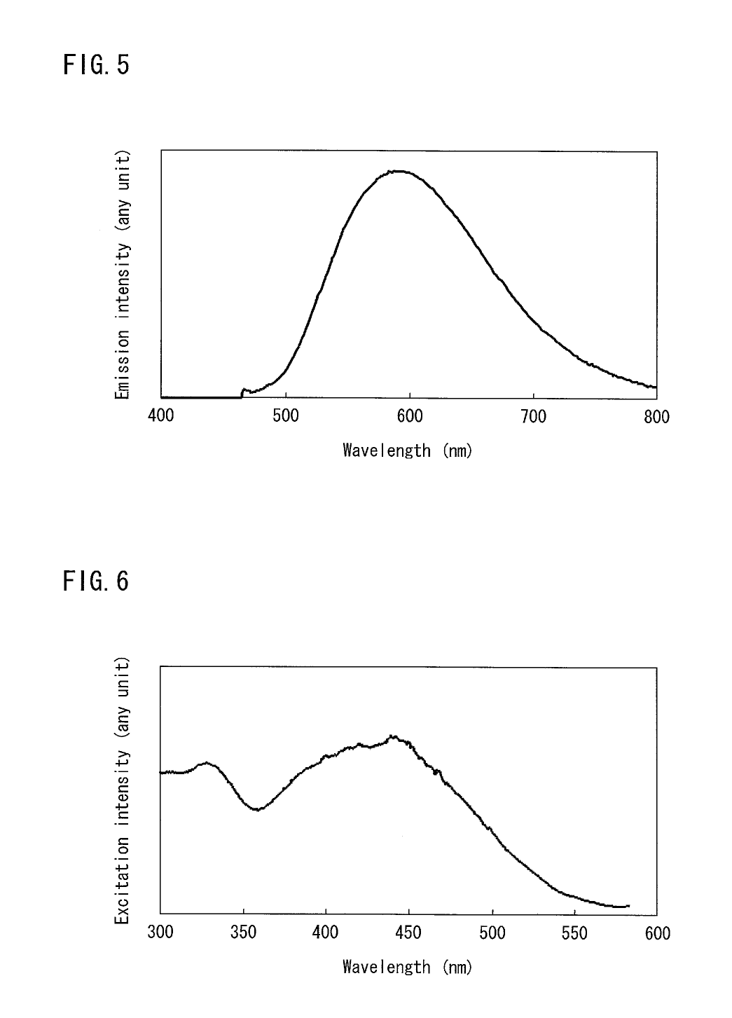

Moreover, FIG. 4 is a graph showing the excitation spectrum of the fluorescent material powder. The longitudinal and lateral axes of FIG. 4 represent excitation intensity (any given unit) and wavelength (nm), respectively.

### Production Example 1-2

### Production 2 of Orange Fluorescent Material

With a crystal of the 0.2CaAlSiN₃.0.8LiSi₂N₃ composition as a host crystal, chemical synthesis was carried out in order to obtain a fluorescent material in which the host crystal is activated with Ce.

Specifically, in order to obtain a compound represented by a theoretical composition formula, Ce_{0.017}Li_{0.1328}Ca_{0.0332}Al_{0.0332}Si_{0.2988}O_{0.0025}N_{0.4979}, operation identical to that of Production Example 1-1 was carried out except that the mixing ratios of Si₃N₄, AlN, Li₃N, Ca₃N₂, and CeO₂ were changed to values shown in Table 1. With this operation, a fluorescent material powder was obtained.

Note that the fluorescent material powder contained an oxide material as a raw material powder, and was therefore in a solid solution crystal form in which Ce and oxygen were dissolved.

Table 2 shows (i) the Ce and Li concentrations of the fluorescent material powder which were obtained with the use of the ICP and (ii) compositions of individual fluorescent materials which were obtained from the Li concentration. Note that the Li concentration, which was lower than 4.90 wt % in the theoretical composition, is considered to be the result of Li evaporation during the calcination and of water-rinsing after the calcination.

As a result of examining the fluorescent material powder with the use of powder X-ray diffraction (XRD), it was confirmed that the fluorescent material powder possesses a crystalline structure in which a CaAlSiN₃ phase is a main phase. Additionally, as a result of radiating the fluorescent material powder with light having a wavelength of 365 nm, it was confirmed that the fluorescent material powder emits orange light in such a condition.

FIG. 5 is a graph showing the emission spectrum of the fluorescent material powder. The longitudinal and lateral axes of FIG. 5 represent emission intensity (any given unit) and wavelength (nm), respectively. Table 3 shows chromaticity coordinates of, a peak wavelength of, and full width at half maximum of the emission spectrum shown in FIG. 5.

Moreover, FIG. 6 is a graph showing the excitation spectrum of the fluorescent material powder. The longitudinal and lateral axes of FIG. 6 represent excitation intensity (any given unit) and wavelength (nm), respectively.

### Production Example 1-3

### Production 3 of Orange Fluorescent Material

With a crystal of the 0.3CaAlSiN₃.0.7LiSi₂N₃ composition as a host crystal, chemical synthesis was carried out in order to obtain a fluorescent material in which the host cell is activated with Ce.

Specifically, in order to obtain a compound represented by a theoretical composition formula, Ce_{0.020}Li_{0.1161}Ca_{0.0497}Al_{0.0497}Si_{0.2819}O_{0.0031}N_{0.4974}, operation identical to that of Production Example 1-1 was carried out except that the mixing ratios of Si₃N₄, AlN, Li₃N, Ca₃N₂, and CeO₂ were changed to values shown in Table 1. With this operation, a fluorescent material powder was obtained. Note that the fluorescent material powder contained an oxide material as a raw material powder, and was therefore in a solid solution crystal form in which Ce and oxygen were dissolved.

Table 2 shows (i) the Ce and Li concentrations of the fluorescent material powder which were obtained with the use of the ICP and (ii) compositions of individual fluorescent materials which were obtained from the Li concentration. Note that the Li concentration, which was lower than 4.16 wt % in the theoretical composition, is considered to be the result of Li evaporation during the calcination and of water-rinsing after the calcination.

As a result of examining the fluorescent material powder with the use of powder X-ray diffraction (XRD), it was confirmed that the fluorescent material powder possesses a crystalline structure in which a CaAlSiN₃ phase is a main phase. Additionally, as a result of radiating the fluorescent material powder with a lamp emitting light having a wavelength of 365 nm, it was confirmed that the fluorescent material powder emits orange light in such a condition.

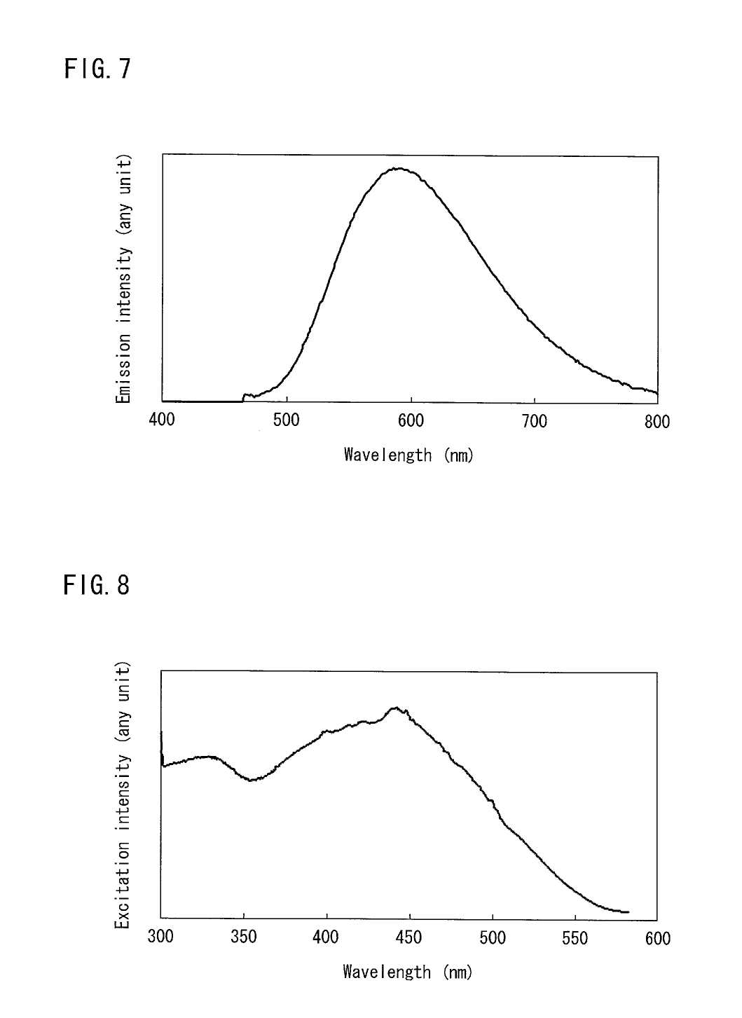

FIG. 7 is a graph showing the emission spectrum of the fluorescent material powder. The longitudinal and lateral axes of FIG. 7 represent emission intensity (any given unit) and wavelength (nm), respectively. Table 3 shows chromaticity coordinates of, a peak wavelength of, and full width at half maximum of the emission spectrum shown in FIG. 7.

Moreover, FIG. 8 is a graph showing the excitation spectrum of the fluorescent material powder. The longitudinal and lateral axes of FIG. 8 represent excitation intensity (any given unit) and wavelength (nm), respectively.

### Production Examples 1-4 through 1-7

### Productions 4 through 7 of Orange Fluorescent Materials

By carrying out an operation identical to that of Production Example 1-1 except that the mixing ratios of Si₃N₄, AlN, Li₃N, Ca₃N₂, and CeO₂ were changed to values shown in Table 1, there were synthesized solid solution crystals in each of which (i) Ce and oxygen were dissolved and (ii) Ce and Li concentrations were changed. Table 2 shows (a) the Ce and Li concentrations of the respective solid solution crystals obtained with the use of the ICP and (b) compositions of the respective fluorescent materials obtained from the respective Li concentrations.

Note that each of the fluorescent material powders contained an oxide material as a raw material powder, and was therefore in a solid solution crystal form in which Ce and oxygen were dissolved.

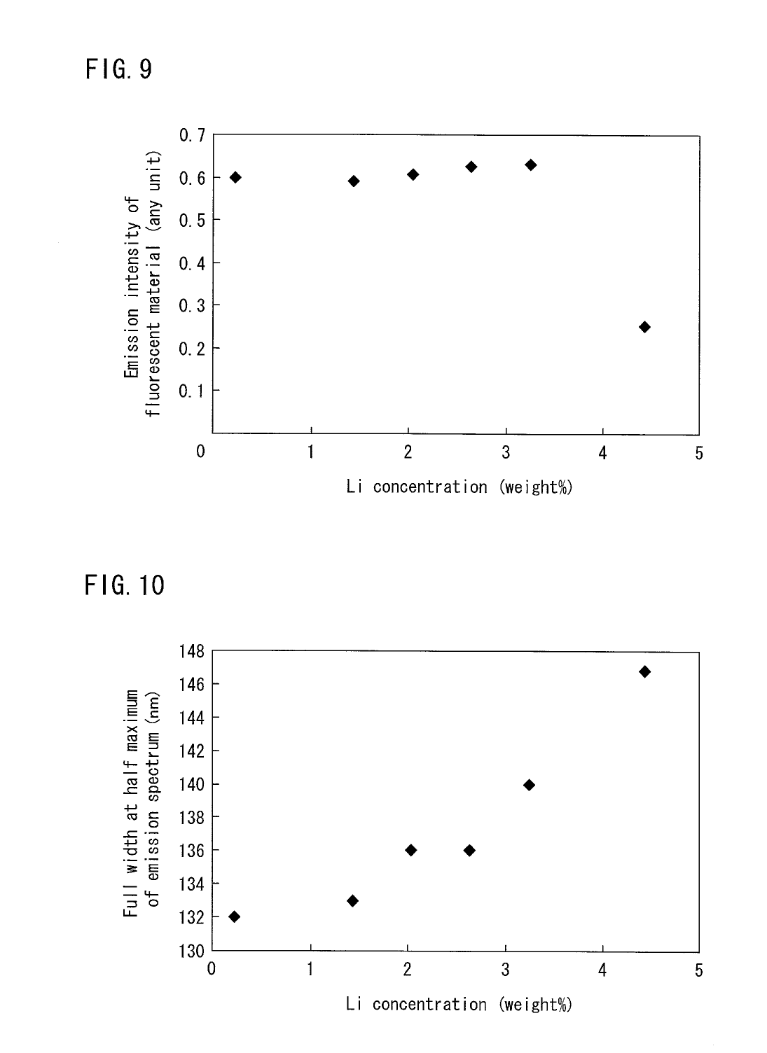

FIG. 9 is a graph showing Li-concentration-dependency of emission intensity of each of the solid solution crystals thus obtained. As shown in FIG. 9, a solid solution crystal having an Li concentration of 4 wt % or less has tendency to show a high emission intensity. The phenomenon that Ce and Li concentrations in a solid solution crystal which deviate from the range mentioned above causes lowering of emission intensity is considered to result from too low concentrations of elements that contribute to light emission, generation of the hetero-phase, etc.

FIG. 10 shows Li-concentration-dependency of full width at half maximum of emission spectrum of each of the solid solution crystals when excited by light having a wavelength of 450 nm. It is found from FIG. 10 that the full width at half maximum of the emission spectrum increases particularly in a case where the Li concentration is 1.5 wt % or more.

Note that the emission intensities described in the present Production Examples were measured with the use of a device in which an MCPD-7000 (manufactured by Otsuka Electronics Co. Ltd.) and an integrating sphere were used in combination.

### Production Example 2

### Production of Eu-Activated β-Sialon Green Fluorescent Material

In order to obtain an Eu-activated β-sialon fluorescent material in which a fluorescent material represented by a composition formula Si_{6-z′}Al_{z′}O_{z′}N_{8-z′}, where z′=0.23 is activated with 0.09 at. % of Eu, powders of α-silicon nitride, aluminum nitride, and europium oxide were weighed with the compositional ratio of 95.82 wt %:3.37 wt %:0.81 wt %, respectively, and the powders thus weighed were mixed for 10 minutes or more with the use of a mortar and a pestle each made of a silicon nitride sintered compact, so that a powder aggregate was obtained. The powder aggregate was dropped in free fall into a boron-nitride pot of 20 mm in both diameter and height.

Next, the pot was placed in a pressurized electric furnace with a graphite resistance heating system. Then, inside of the electric furnace was vacuumized with the use of a diffusion pump, a temperature of the inside of the electric furnace was raised from a room temperature to 800° C. at speed of 500° C. per hour, nitrogen with 99.999 volume % purity was introduced into the inside of the electric furnace so as to set the atmospheric pressure there to 1 MPa, the temperature of the inside of the electric furnace was raised to 1900° C. at speed of 500° C. per hour, and the temperature of the inside of the electric furnace was maintained at 1900° C. for 8 hours, so that a fluorescent material powder sample was obtained. The fluorescent material sample thus obtained was crushed in an agate mortar, so that a fluorescent material sample was obtained. The fluorescent material sample thus obtained was crushed in an agate mortar and then subjected to a 1:1 mixed acid consisting of 50% of hydrofluoric acid and 70% of nitric acid, so that a fluorescent material powder was obtained.

As a result of examining the fluorescent material powder with the use of powder X-ray diffraction (XRD), all charts obtained from the fluorescent material powder indicate that the fluorescent material powder possesses a β-sialon structure. Furthermore, as a result of radiating the fluorescent material powder with a lamp emitting light having a wavelength of 365 nm, it was confirmed that the fluorescent material powder emits green light in such a condition.

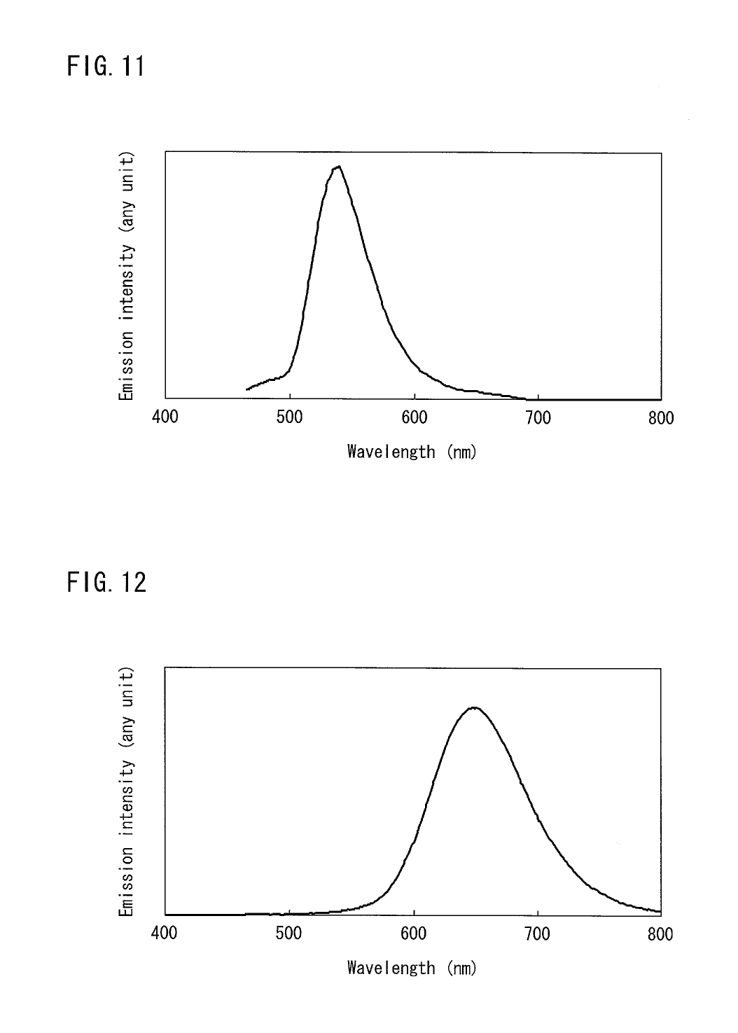

As a result of measuring the emission spectrum of the Eu-activated β-sialon fluorescent material powder thus obtained, an emission spectrum shown in FIG. 11 was obtained. The longitudinal and lateral axes of FIG. 11 represent emission intensity (any given unit) and wavelength (nm), respectively. Chromaticity coordinates, peak wavelength, and full width at half maximum of the emission spectrum shown in FIG. 11 are shown in Table 3.

As a result of measuring an oxygen amount in the synthesized powder with the use of an oxygen/nitrogen analyzer based on a combustion method (TC 436 model, manufactured by LECO Corporation), the oxygen content was 1.12 wt %. As a result of measuring an absorption factor of light having a wavelength of 600 nm with the use of an MCPD-7000 (manufactured by Otsuka Electronics Co. Ltd.), the absorption factor was 9.1%.

### Production Example 3

### Production of Eu-Activated CaAlSiN₃ Red Fluorescent Material

29.7 wt % of aluminum nitride powder, 33.9 wt % of α-silicon nitride powder, 35.6 wt % of calcium nitride powder, and 0.7 wt % of europium nitride powder were weighed, and the powders thus weighed were mixed using a mortar and a pestle each made of a silicon nitride sintered compact for 10 minutes or more, so that a powder aggregate was obtained. The europium nitride was synthesized by azotizing metal europium in aluminum. The powder aggregate was dropped in free fall into a boron-nitride pot of 20 mm in both diameter and height. Note that all the steps of weighing, mixing, and molding of the powders were carried out in a glove box capable of maintaining therein a nitrogen atmosphere in which the moisture content and the oxygen content are each 1 ppm or less.

Subsequently, the pot was placed in an electric furnace with a graphite resistance heating system, nitrogen with 99.999 volume % purity was introduced into the inside of the electric furnace so as to set the atmospheric pressure to 1 MPa, the temperature of the inside of the electric furnace was raised to 1800° C. at speed of 500° C. per hour, and the temperature of the inside of the electric furnace was maintained at 1800° C. for 2 hours, so that a fluorescent material sample was obtained. The fluorescent material sample thus obtained was crushed using an agate mortar, so that a fluorescent material powder was obtained. As a result of examining the fluorescent material powder by powder X-ray diffraction (XRD) using a Ka line of Cu, it is found that the fluorescent material powder has a crystalline structure of CaAlSiN₃. Furthermore, as a result of radiating the fluorescent material powder with a lamp emitting light of 365 nm in wavelength, it was confirmed that the fluorescent material powder emits red light.

As a result of measuring the emission spectrum of the Eu-activated CaAlSiN₃ fluorescent material powder thus obtained, an emission spectrum shown in FIG. 12 was obtained. The longitudinal and lateral axes of FIG. 12 represent emission intensity (any given unit) and wavelength (nm), respectively. Chromaticity coordinates, peak wavelength, and full width at half maximum of the emission spectrum shown in FIG. 12 are shown in Table 3.

TABLE 1

| | Mixing ratio of raw material powder | | | | |
|---|---|---|---|---|---|
| Production | (weight %) | | | | |
| Example | CeO₂ | Li₃N | Ca₃N₂ | AlN | Si₃N₄ |
| 1-1 | 1.4 | 3.7 | 23.5 | 19.5 | 51.9 |
| 1-2 | 1.5 | 8.2 | 8.7 | 7.2 | 74.3 |
| 1-3 | 1.8 | 7.0 | 12.7 | 10.5 | 68.0 |
| 1-4 | 1.3 | 1.8 | 29.8 | 24.8 | 42.4 |
| 1-5 | 1.4 | 4.7 | 20.1 | 16.7 | 57.1 |
| 1-6 | 1.4 | 5.8 | 16.5 | 13.7 | 62.5 |
| 1-7 | 3.1 | 9.4 | 4.4 | 3.7 | 79.5 |

TABLE 2

| Production | Result of ICP measurement | | Composition of |
|---|---|---|---|
| Example | Li weight % | Ce weight % | fluorescent material |
| 1-1 | 1.43 | 1.12 | 0.76CaAlSiN₃•0.24LiSi₂N₃ |
| 1-2 | 3.85 | 1.25 | 0.35CaAlSiN₃•0.65LiSi₂N₃ |
| 1-3 | 3.25 | 1.52 | 0.45CaAlSiN₃•0.55LiSi₂N₃ |
| 1-4 | 0.23 | 1.07 | 0.96CaAlSiN₃•0.04LiSi₂N₃ |
| 1-5 | 2.04 | 1.15 | 0.65CaAlSiN₃•0.35LiSi₂N₃ |
| 1-6 | 2.64 | 1.18 | 0.55CaAlSiN₃•0.45LiSi₂N₃ |
| 1-7 | 4.43 | 2.53 | 0.25CaAlSiN₃•0.75LiSi₂N₃ |

TABLE 3

| | Peak | Full width at half | | |
|---|---|---|---|---|
| Production | wavelength | maximum of emission | | |
| Example | (nm) | spectrum (nm) | u′ | v′ |
| 1-1 | 579 | 134 | 0.244 | 0.559 |
| 1-2 | 596 | 147 | 0.258 | 0.558 |
| 1-3 | 593 | 140 | 0.259 | 0.558 |
| 2 | 540 | 53 | 0.129 | 0.570 |
| 3 | 650 | 94 | 0.455 | 0.531 |

### Preparation of Semiconductor Light-Emitting Device

### Examples 1-6

The fluorescent materials shown in Table 4 were each mixed with silicone resin (product name: KER2500, Shin-Etsu Silicone) with the weight ratios shown in Table 5, so that mold resins in which the fluorescent materials were dispersed were prepared. Using the mold resins, semiconductor light-emitting devices having the structure shown in FIG. 1 in accordance with Examples 1-6 were manufactured.

The semiconductor light-emitting element used here was an LED having an emission peak wavelength shown in Table 4 (product name: EZR, Cree, Inc.).

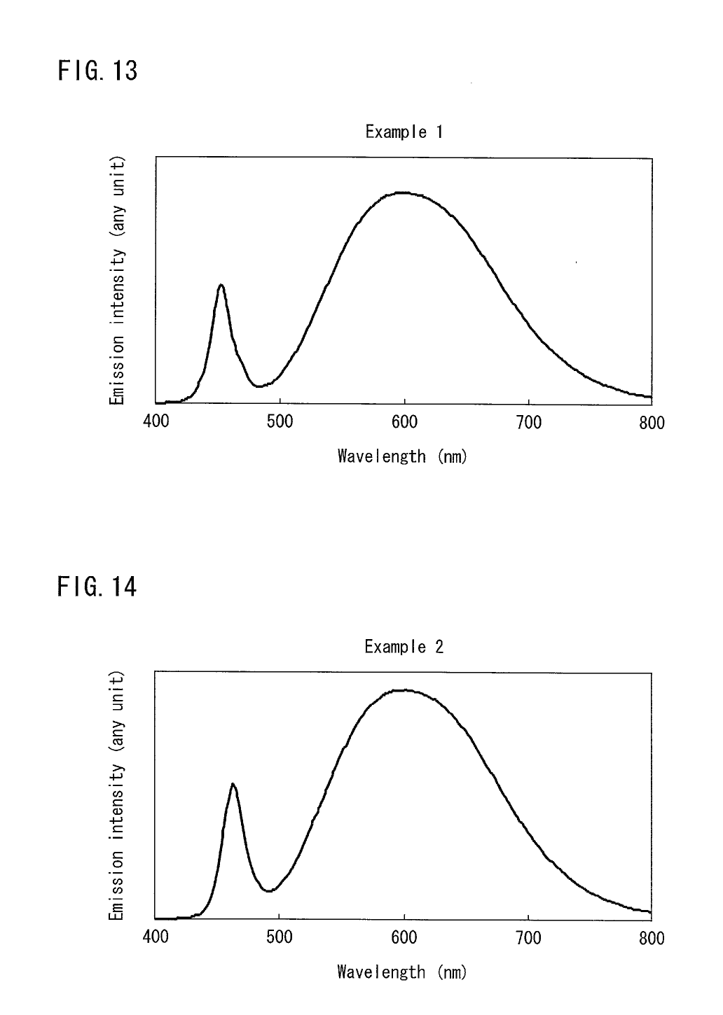

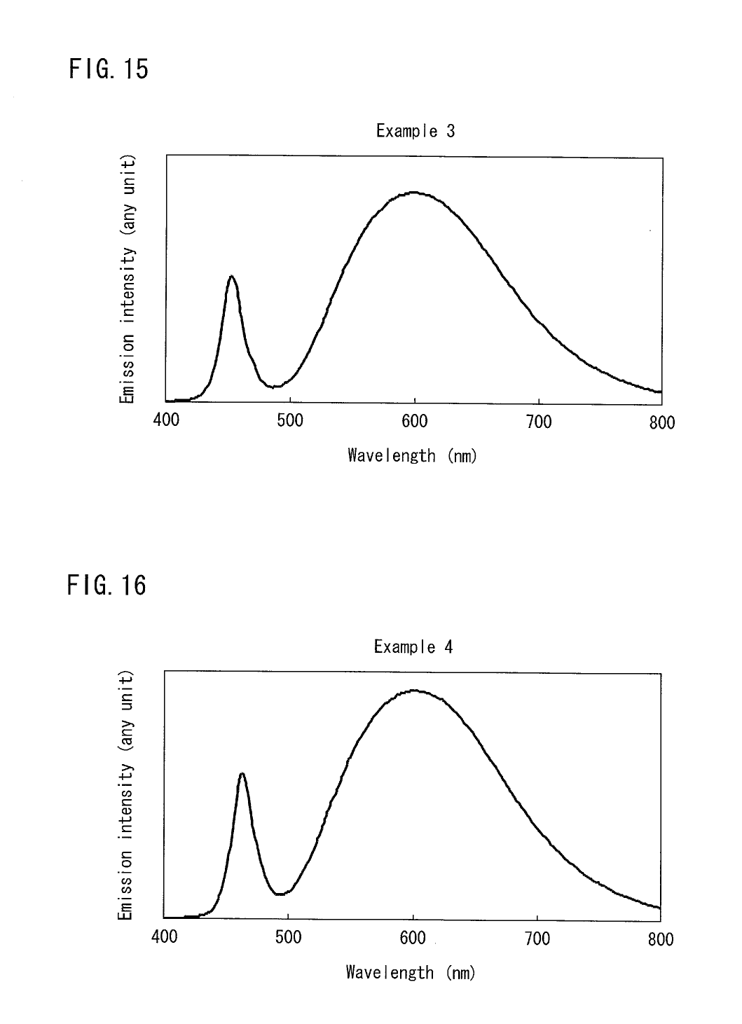

Here, the mixing ratios of the mold resins and the peak wavelength of the LED were controlled so that the correlated color temperatures of the individual light-emitting devices were in a lamp color region. FIGS. 13-18 show emission spectra of the semiconductor light-emitting devices exemplified in the present Examples, and Table 6 shows characteristics of the semiconductor light-emitting devices. In FIGS. 13-18, the longitudinal and lateral axes indicate emission intensity (any unit) and wavelength (nm), respectively. In Table 6, TCP indicates correlated color temperature (unit: K), Duv indicates deviation, and u′ and v′ indicate color coordinates.

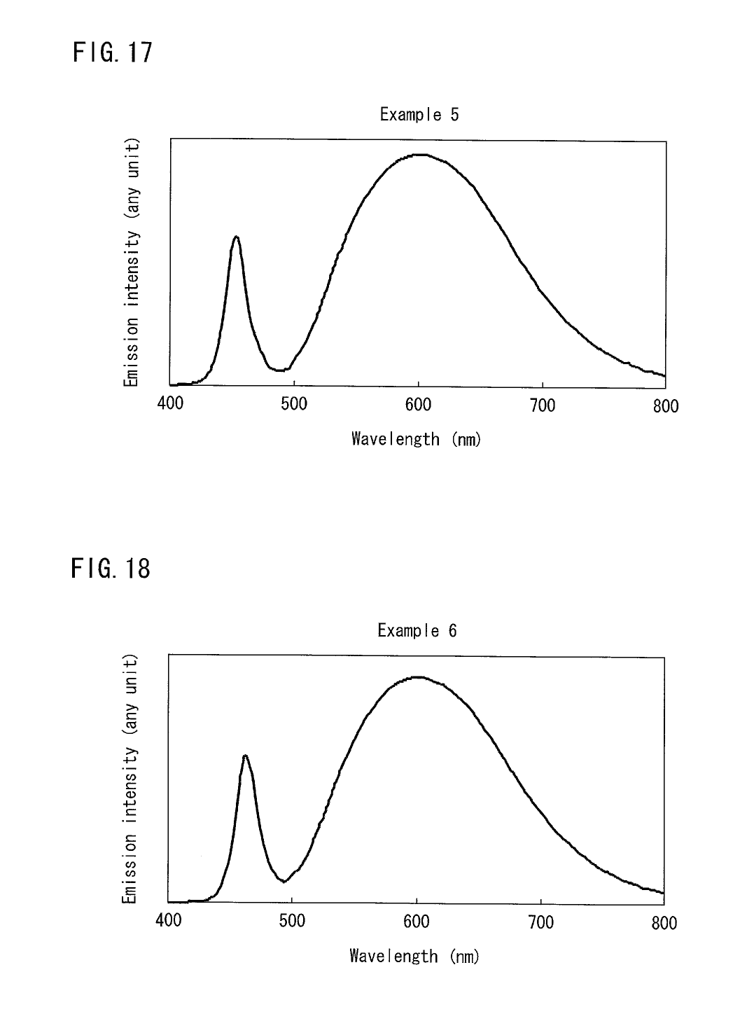

The light-emitting device of the present invention is designed such that when the light-emitting element that emits blue light emits blue light to at least the orange fluorescent material and the red fluorescent material, white light in a lamp color region is emitted. In Examples 1-4, when the LED emitted, to the orange fluorescent material and the red fluorescent material, blue light whose emission spectrum peak was at the wavelength shown in Table 4, white light in a lamp color region with emission spectra shown in FIGS. 13-16, respectively, was emitted. In Examples 5 and 6, when the LED emitted, to the orange fluorescent material, the red fluorescent material, and the green fluorescent material, blue light whose emission spectrum peak was at the wavelength shown in Table 4, white light in a lamp color region with emission spectra shown in FIGS. 17 and 18, respectively, was emitted.

### Comparative Example 1

The Ce-activated YAG fluorescent material was mixed with the red fluorescent material produced in Production Example 3 and the mixture was dispersed in silicone resin (product name: KER2500, Shin-Etsu silicone) with a weight ratio of (Ce-activated YAG fluorescent material):(red fluorescent material produced in Production Example 3):(Silicone resin) being 1.000:0.080:0.041, so that mold resin was obtained. Using the mold resin, there was produced a semiconductor light-emitting device having a structure similar to that shown in FIG. 1 in accordance with Comparative Example 1.

The Ce-activated YAG fluorescent material used here was “P46-Y3” (product name) manufactured by Kasei Optonix, Ltd. The Ce-activated YAG fluorescent material which was a yellow fluorescent material was designed such that when excited by light of 460 nm, peak wavelength of emission spectrum was 557 nm, full width at half maximum of emission spectrum was 117 nm, and chromaticity coordinates were (u′, v′)=(0.210, 0.565).

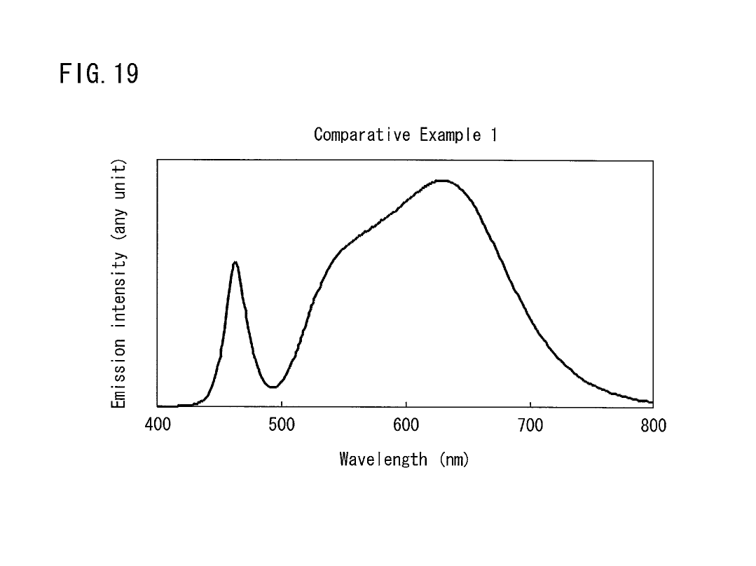

The semiconductor light-emitting element used here was an LED having an emission peak wavelength at 460 nm (product name: EZR, Cree, Inc.). Here, the mixing ratios of the mold resins and the peak wavelength of the LED were controlled so that the correlated color temperatures of the individual light-emitting devices were in a lamp color region. Thus, emission spectrum shown in FIG. 19 and characteristics shown in Table 6 were obtained. In FIG. 19, the longitudinal and lateral axes indicate emission intensity (any unit) and wavelength (nm), respectively.

The emission spectra of the semiconductor light-emitting devices that were shown in FIGS. 13-19 were measured by a spectrophotometer (product name: MCPD-7000, manufactured by Otsuka Electronics Co. Ltd.), and indices shown in Table 6 were calculated based on the emission spectra thus measured. Luminous efficiencies (luminous intensity) of the semiconductor light-emitting devices were measured by a measurement system in which a spectrophotometer (product name: MCPD-7000, manufactured by Otsuka Electronics Co. Ltd.) was combined with an integrating sphere.

It is found from the result shown in Table 6 that the semiconductor light-emitting devices shown in Examples exhibit higher luminous efficiency than the semiconductor light-emitting devices shown in Comparative Examples. This is because the semiconductor light-emitting devices shown in Examples each have an orange fluorescent material which is a Ce-activated CaAlSiN₃ fluorescent material and which is made up of a solid solution crystal in which Ce and oxygen are dissolved in a crystal with a composition of cCaAlSiN₃.(1−c)LiSi₂N₃ where 0.2≦c≦0.8, and consequently the semiconductor light-emitting devices shown in Examples have a remarkably low weight ratio of (red fluorescent material)/(fluorescent material other than red fluorescent material) than the semiconductor light-emitting devices shown in Comparative Examples.

Although the values of Ra and R9 of the semiconductor light-emitting devices shown in Examples are smaller than those of the semiconductor light-emitting devices shown in Comparative Examples, the values of Ra and R9 of the semiconductor light-emitting devices shown in Examples meet conditions that Ra>70 and R9>0 and are sufficient for the semiconductor light-emitting devices of Examples to be used for general home applications and vehicle lighting appliances.

Comparison of Examples 1 and 2 with Examples 3 through 6 shows that the semiconductor light-emitting devices shown in Examples 3 through 6 exhibit higher luminous efficiency. This is because the semiconductor light-emitting devices shown in Examples 3 and 4 each have particularly broad full width at half maximum of emission spectrum of the orange fluorescent material, and because the semiconductor light-emitting devices shown in Examples 5 and 6 each include the green fluorescent material in addition to the orange fluorescent material.

TABLE 4

| | LED peak | Orange | Red | Green | Yellow |
|---|---|---|---|---|---|
| | wave- | fluo- | fluo- | fluo- | fluo- |
| | length | rescent | rescent | rescent | rescent |
| | (nm) | material | material | material | material |
| Example 1 | 450 | Production | Production | — | — |
| | | Example | Example 3 | | |
| | | 1-1 | | | |
| Example 2 | 460 | Production | Production | — | — |
| | | Example | Example 3 | | |
| | | 1-1 | | | |
| Example 3 | 450 | Production | Production | — | — |
| | | Example | Example 3 | | |
| | | 1-2 | | | |
| Example 4 | 460 | Production | Production | — | — |
| | | Example | Example 3 | | |
| | | 1-2 | | | |
| Example 5 | 450 | Production | Production | Production | — |
| | | Example | Example 3 | Example 2 | |
| | | 1-3 | | | |
| Example 6 | 460 | Production | Production | Production | — |
| | | Example | Example 3 | Example 2 | |
| | | 1-3 | | | |
| Comparative | 460 | — | Production | — | Ce- |
| Example 1 | | | Example 3 | | activated |
| | | | | | YAG |

TABLE 5

| | | | | | | Weight ratio of |
|---|---|---|---|---|---|---|
| | | | | | | (red fluorescent |
| | | | | | | material/ |
| | Weight ratio of fluorescent material | | | | | fluorescent |
| | | | Red | Green | Yellow | material |
| | | Orange | fluo- | fluo- | fluo- | other than red |
| | | fluorescent | rescent | rescent | rescent | fluorescent |
| | resin | material | material | material | material | material) |
| Ex. 1 | 1.000 | 0.152 | 0.018 | — | — | 0.12 |
| Ex. 2 | 1.000 | 0.149 | 0.018 | — | — | 0.12 |
| Ex. 3 | 1.000 | 0.178 | 0.006 | — | — | 0.03 |
| Ex. 4 | 1.000 | 0.165 | 0.008 | — | — | 0.05 |
| Ex. 5 | 1.000 | 0.141 | 0.012 | 0.018 | — | 0.08 |
| Ex. 6 | 1.000 | 0.141 | 0.010 | 0.017 | — | 0.06 |
| Com. | 0.041 | — | 0.080 | — | 1.000 | 0.51 |
| Ex. 1 | | | | | | |

TABLE 6

| | | | | | | | Relative |
|---|---|---|---|---|---|---|---|
| | | | | | | | luminous |
| | | | | | | | efficiency |
| | | | | | | | of LED |
| | Ra | R9 | TCP | Duv | u′ | v′ | (%) |
| Example 1 | 74.3 | 7.1 | 2797.6 | 1.21 | 0.258 | 0.527 | 100.00 |
| Example 2 | 76.5 | 11.4 | 2820.1 | 2.83 | 0.257 | 0.529 | 102.00 |
| Example 3 | 72.8 | 2.6 | 2792.3 | −0.27 | 0.259 | 0.525 | 107.90 |
| Example 4 | 75.8 | 9.8 | 2795.4 | 0.63 | 0.258 | 0.526 | 108.90 |
| Example 5 | 74.3 | 10.2 | 2836.6 | −0.43 | 0.257 | 0.524 | 102.10 |
| Example 6 | 76.2 | 11.6 | 2826.5 | 0.89 | 0.257 | 0.526 | 104.10 |
| Comparative | 85.0 | 49.1 | 2818.5 | 0.45 | 0.257 | 0.526 | 87.60 |
| Example 1 | | | | | | | |

### INDUSTRIAL APPLICABILITY

The light-emitting device of the present invention exhibits high luminous efficiency and emits lamp color light with high Ra and R9. Accordingly, the light-emitting device of the present invention can be used appropriately for various illumination instruments such as home illumination instruments and vehicle lighting appliances.

### REFERENCE SIGNS LIST

1 Light-emitting device
2 Light-emitting element
3 Printed wiring substrate
4 Resin frame
5 Mold resin
6 InGaN layer
7 p-side electrode
8 n-side electrode
9 n-electrode section
10 Adhesive
11 p-electrode section
12 Metal wire
13 Orange fluorescent material
14 Red fluorescent material

1. A light-emitting device for emitting white light in a lamp color region, comprising at least a light-emitting element for emitting blue light, an orange fluorescent material which absorbs the blue light so as to emit orange light, and a red fluorescent material which absorbs the blue light so as to emit red light, the orange fluorescent material being a Ce-activated CaAlSiN₃ fluorescent material in a solid solution crystal form in which Ce and oxygen are dissolved in a crystal having a composition of cCaAlSiN₃.(1−c)LiSi₂N₃ where 0.2≦c≦0.8.

2. The light-emitting device as set forth in claim 1, wherein a weight ratio of the red fluorescent material to a fluorescent material other than the red fluorescent material is less than 0.2.

3. The light-emitting device as set forth in claim 1, wherein full width at half maximum of emission spectrum of the orange fluorescent material is not less than 130 nm.

4. The light-emitting device as set forth in claim 1, wherein the orange fluorescent material contains Li in a range of not less than 1.4 weight % and not more than 4 weight %.

5. The light-emitting device as set forth in claim 1, wherein the red fluorescent material is an Eu-activated nitride fluorescent material or an oxynitride fluorescent material.

6. The light-emitting device as set forth in claim 1, wherein full width at half maximum of emission spectrum of the red fluorescent material is not less than 70 nm.

7. The light-emitting device as set forth in claim 1, wherein the red fluorescent material is an Eu-activated MAlSiN₃ fluorescent material (M=Ca, Sr).

8. The light-emitting device as set forth in claim 1, further comprising a green fluorescent material in addition to the red fluorescent material and the orange fluorescent material.

9. The light-emitting device as set forth in claim 8, wherein full width at half maximum of emission spectrum of the green fluorescent material is not more than 55 nm.

10. The light-emitting device as set forth in claim 8, wherein the green fluorescent material is an Eu-activated β sialon fluorescent material.

11. The light-emitting device as set forth in claim 10, wherein an absorption ratio of light of the Eu-activated β sialon fluorescent material at 600 nm is not more than 10%.
